(19) United States
(12) Patent Application Publication
(10) Pub. No.: US 2014/0078436 A1
(43) Pub. Date: Mar. 20, 2014

(54) PIXEL STRUCTURE FOR LIQUID CRYSTAL DISPLAY, ARRAY SUBSTRATE AND LIQUID CRYSTAL DISPLAY

(71) Applicant: BEIIJING BOE OPTOEELECTRONICS TECHNOLOHY CO., LTD, Beijing, CN (US)

(72) Inventors: Lianjie Qu, Beijing (CN); Jian Guo, Beijing (CN)

(73) Assignee: BEILING BOE OPTOELECTRONICS TECHNOLOGY CO.,LTD., Beijing (CN)

(21) Appl. No.: 13/995,330

(22) PCT Filed: Nov. 28, 2012
(86) PCT No.: PCT/CN2012/085477

§ 371 Date: Jun. 18, 2013

(30) Foreign Application Priority Data
Jul. 16, 2012 (CN) 201210245872.5

(51) Int. Cl. G02F 1/1343; H01L 27/15; H01L 29/786

(52) U.S. Cl. CPC G02F 1/134309; H01L 29/786; H01L 27/156
USPC 349/42; 257/57; 257/59

(57) ABSTRACT

There are disclosed a pixel structure for a liquid crystal display, an array substrate and the liquid crystal display, for enhancing stability of picture quality of the liquid crystal display. The pixel structure for the liquid crystal display comprises: gate lines (3), a common electrode (2), a thin film transistor, data lines (10) and a pixel electrode (9), wherein the pixel electrode (9) includes a plurality of strip-like portions, and at least one of the strip-like portions of the pixel electrode (9) is placed to overlap a part of a corresponding gate line (3) entirely or in part.

### TECHNICAL FIELD

Embodiments of the present disclosure relate to a pixel structure for a liquid crystal display, an array substrate, and the liquid crystal display.

### BACKGROUND

Thin film transistor liquid crystal displays (TFT-LCDs) have characteristics of small volume, low power consumption, irradiation-free, etc., and play a leading role in the current market for flat panel displays. In an advanced super dimension switch (briefly “ADS”) technology, a multi-dimensional electric field is formed by an electric field produced at edges of slit electrodes on the same plane and an electric field produced between a layer of the slit electrodes and a layer of a plate-like electrode, so as to allow liquid crystal molecules at every alignment within a liquid crystal cell, which are located directly above the electrode and between the slit electrodes, to be rotated, and thereby the work efficiency of liquid crystals is enhanced and the transmissive efficiency is increased. The advanced super dimension switch technology can improve the picture quality of TFT-LCD products, and has advantages of high resolution, high transmittance, low power consumption, wide viewing angle, high opening ratio, low chromatic aberration, push mura-free, etc.

A TFT-LCD array substrate of an ADS mode is usually completed with a plurality of patterning processes. Each of the patterning processes may include: masking, exposing, developing, etching, stripping and other process. The etching process comprises drying etching and wet etching.

For example, the process by which the TFT-LCD array substrate is completed through five patterning processes includes: forming a transparent common electrode on a glass substrate through a first patterning process; forming gate lines and data lines that are even-numbered are foamed through a second patterning process; forming an active layer, source and drain metal electrodes of thin film transistors (TFTs) and data lines that are odd-numbered through a third patterning process; forming a passivation layer and via holes through a fourth patterning process; and depositing a transparent conductive layer and forming pixel electrodes through a fifth patterning process.

A cross-section view of a pixel structure for one pixel unit of the TFT-LCD array substrate that is formed by the above method is shown in FIG. 1. The pixel structure comprises: a glass substrate 1, a common electrode 2, a gate electrode 3, a metal-insulated layer 4, an active layer 5, source and drain metal electrodes 6, a passivation layer 7, a via hole 8 and a pixel electrode 9. A plan view of the pixel structure of the TFT-LCD array substrate is shown in FIG. 2. The pixel electrode 9 comprises a plurality of strip-like portions. The width of each of the strip-like portions of the pixel electrode 9 is “a.”

A common electrode is included in this TFT-LCD array substrate structure, and thus a storage capacitor is usually formed with a common electrode line; namely, the storage capacitor is constituted by the common electrode and the pixel electrode.

When the TFT-LCD operates, a pixel-point potential difference will occur after changing for pixel electrodes ends, i.e., a leaping voltage ΔVp, and the leaping voltage is:

$$Δ {V}_{p} = \frac{( {V}_{gh} - {V}_{gl} ) \times {C}_{gs}}{( {C}_{st} + {C}_{lc} )} \qquad ( 1 )$$

where V_{gh} is a switched-on voltage of gate electrode, V_{gl} is a switched-off voltage of gate electrode. C_{gs} is parasitic capacitance, C_{lc} is liquid crystal capacitance, Cₛₜ is storage capacitance, and C_{gs}<<Cₛₜ+C_{lc}.

As can be known from the formula (1), when the storage capacitance Cₛₜ of the TFT-LCD varies, different leaping voltages ΔVₚ occur, thereby resulting in the fact that brightness throughout a panel of the TFT-LCD varies. Where a pixel electrode on the array substrate includes a plurality of strip-like portions, when widths “a” of strip-like portions of pixel electrodes are different from each other, areas of the pixel electrodes covering common electrodes are different. Thereby, there are different values of storage capacitance throughout the panel of the TFT-LCD.

As can be seen, the leaping voltage ΔV_{S}, changes when the widths “a” of strip-like portions of a pixel electrode changes; namely, the leaping voltage ΔVₚ is relatively sensitive to variation in the widths “a” of the strip-like portions of the pixel electrode. In an existing process for forming TFT-LCD array substrates, due to used equipments, it cannot be ensured that the widths “a” of strip-like portions of a pixel electrode in an array substrate that is formed every time is equal yet. That is, it cannot be ensured that widths of strip-like portions of pixel electrodes for array substrate products of the same design specification are the same as each other.

Therefore, regarding an existing TFT-LCD of the ADS mode, the problem that a panel has uneven brightness may still exist, and the picture quality may not be very stable.

### SUMMARY

Embodiments of the present disclosure provide a pixel structure for a liquid crystal display, an array substrate and the liquid crystal display, for enhancing stability of picture quality of the liquid crystal display.

According to an embodiment of the present disclosure, there is provided a pixel structure for a liquid crystal display, comprising: gate lines disposed on two opposite sides, data lines disposed on other two opposite sides, a common electrode, a thin film transistor and a pixel electrode, wherein the pixel electrode includes a plurality of strip-like portions, and at least one of the strip-like portions of the pixel electrode is placed to overlap a part of a corresponding gate line entirely or in part.

According to another embodiment of the present disclosure, there is provided an array substrate of a liquid crystal display, comprising at least one above-mentioned pixel structure.

According to still another embodiment of the present disclosure, there is provided a liquid crystal display, comprising the above array substrate.

In the pixel structure according to the embodiments of the present disclosure, the storage capacitance C_{gsl} between a pixel electrode and a gate line and the storage capacitance Cₛₜ between the pixel electrode and a common electrode can be increased or decreased synchronously in accordance with variation in widths “a” of strip-like portions of the pixel electrode. Thus, sensitivity of a leaping voltage ΔVₚ to variation in the widths “a” of the strip-like portions of the pixel electrode in a process is reduced, and further, the probability that uneven brightness of the panel of a TFT-LCD occurs due to the process is reduced, thereby enhancing stability of the picture quality.

### BRIEF DESCRIPTION OF THE DRAWINGS

In order to illustrate the technical solution of the embodiments of the invention more clearly, the drawings of the embodiments will be briefly described below; it is obvious that the drawings as described below are only related to some embodiments of the present disclosure, but not limitative of the present disclosure.

FIG. 1 is a cross-sectional view showing a pixel structure for an existing TFT-LCD array substrate;

FIG. 2 is a plan view showing the pixel structure for the existing TFT-LCD array substrate in prior art;

FIG. 3 is a plan view showing a pixel structure for a TFT-LCD array substrate in an embodiment according to the present disclosure; and

FIG. 4 is a cross-sectional view showing the pixel structure for the TFT-LCD array substrate in the embodiment according to the present disclosure.

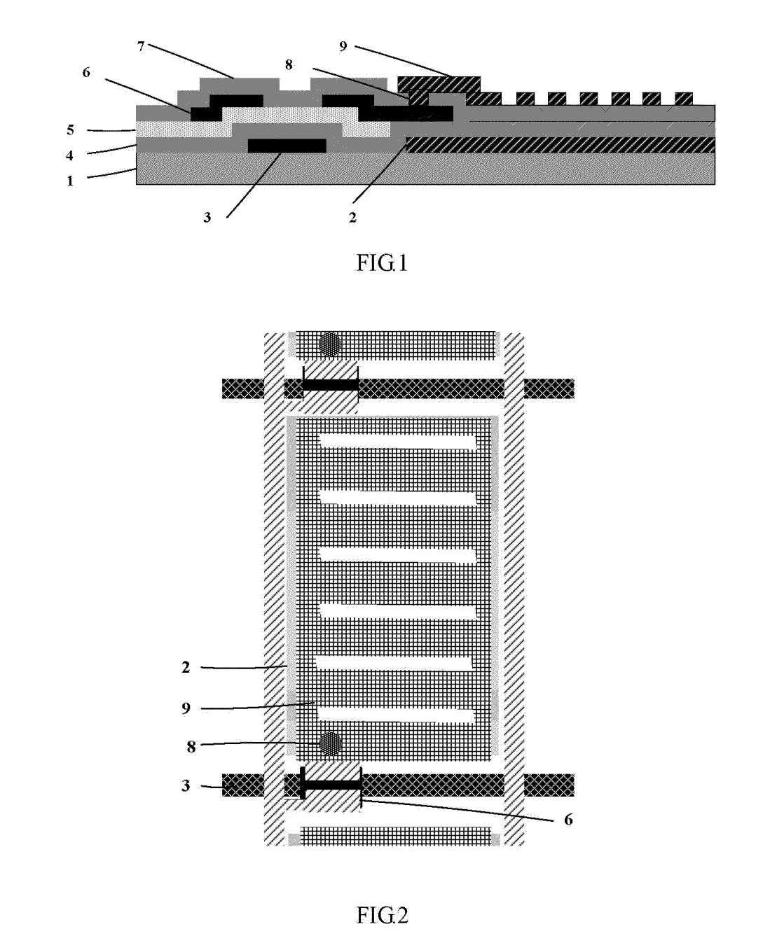

### DETAILED DESCRIPTION

In order to make objects, technical details and advantages of the embodiments of the present disclosure apparent, hereinafter, the technical solutions of the embodiments of the present disclosure will be described in a clearly and fully understandable way in connection with the drawings related to the embodiments of the present disclosure. It is obvious that the described embodiments are just a part but not all of the embodiments of the present disclosure. Based on the described embodiments of the present disclosure, those ordinarily skilled in the art can obtain other embodiment(s), without any inventive work, which should be within the scope sought for protection by the present disclosure.

Unless otherwise defined, the technical or scientific terminology used herein should have the same meaning as commonly understood by one of ordinary skill in the art to which this invention belongs. Terms such as “first”, “second” and the like used in specification and claims of the patent application of the invention do not show any order, number or importance, but are only used to distinguish different constituent parts. Likewise, a term “a,” “an,” or the like does not indicate limitation in number, but specifies the presence of at least one. A term such as “comprises,” “comprising,” “includes,” “including”, “contains” or the like means that an element or article ahead of this term encompasses element(s) or article(s) listed behind this term and its (their) equivalents, but does not preclude the presence of other elements or articles. A term such as “connection,” “connected,” or the like is not limited to physical or mechanical connection, but can include electrical connection, whether directly or indirectly. “Upper,” “lower,” “left,” “right” or the like is only used to describe a relative positional relationship, and when the absolute position of a described object is changed, the relative positional relationship might also be changed accordingly.

An array substrate according to an embodiment of the invention includes a plurality of gate lines and a plurality of data lines, and these gate lines and data lines cross over each other to thereby define a plurality of pixel units arranged in a matrix form. Each of the pixel units includes a thin film transistor functioning as a switch element and a pixel electrode and a common electrode that act to control alignment of liquid crystals. For example, for the thin film transistor of each pixel, its gate electrode is electrically connected to or integrally formed with a corresponding gate line, its source electrode is electrically connected to or integrally formed with a corresponding data line, and its drain electrode is electrically connected to or integrally formed with a corresponding pixel electrode. The following descriptions are mainly made on a single pixel unit or a plurality of pixel units, but other pixel unit(s) can be formed in the same way.

In an embodiment of the present disclosure, with respect to a pixel structure for a TFT-LCD array substrate in which a storage capacitor is formed on a common electrode line, in order to reduce the sensitivity of a leaping voltage ΔV_{E}, to variation in the widths “a” of strip-like portions of a pixel electrode, the coverage area of a pixel electrode is increased, and the pixel electrode is extended to a position corresponding to a gate line, so that a part of the pixel electrode is placed to overlap a part of the corresponding gate line. As such, an additional storage capacitance C_{gsl} is produced between the pixel electrode and the gate line, and the storage capacitance C_{gsl} between the pixel electrode and the gate line and the storage capacitance Cₛₜ between the pixel electrode and a common electrode can be increased or decreased synchronously in accordance with variation in the widths of the strip-like portions of the pixel electrode. This can reduce sensitivity of the leaping voltage ΔVₚ to variation in the widths of the strip-like portions of the pixel electrode in a process, and the probability that uneven brightness of a panel of the TFT-LCD occurs due to manufacturing processes is reduced, thereby enhancing stability of the picture quality of the liquid crystal display.

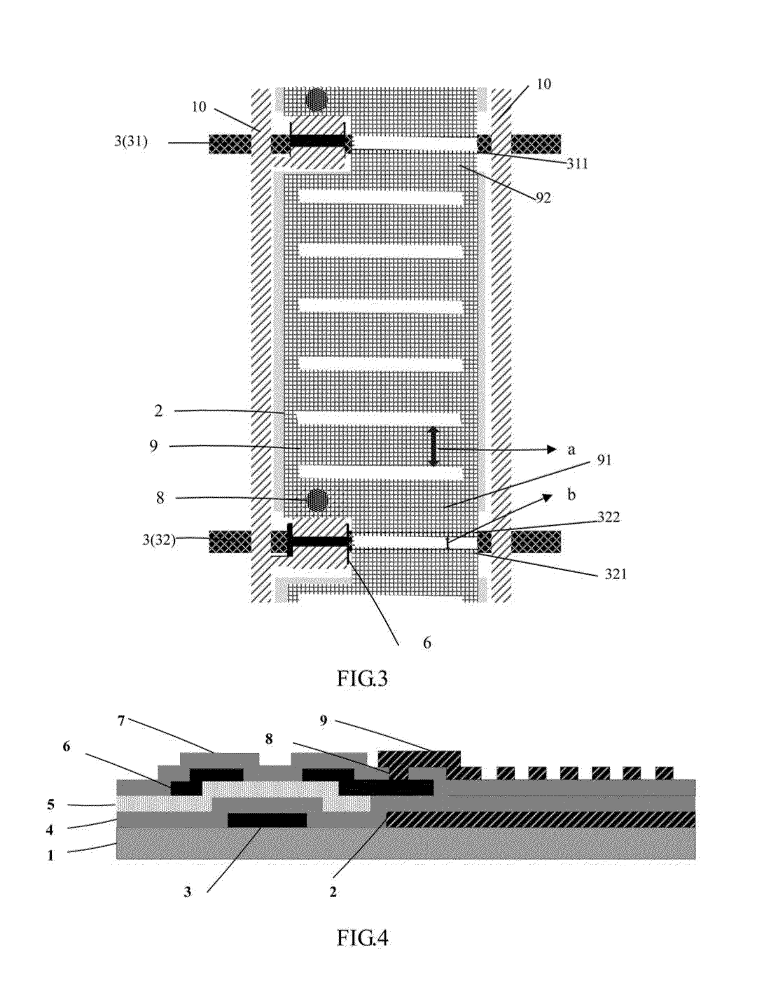

FIG. 3 is a plan view showing a pixel structure corresponding to one pixel unit of a TFT-LCD array substrate in an embodiment of the invention; and FIG. 4 is a cross-sectional view showing the pixel structure for the TFT-LCD array substrate in the embodiment of the present disclosure.

The pixel structure includes: a common electrode 2, gate lines 3 (31, 32), a thin film transistor over one gate line 3, a via hole 8, a pixel electrode 9 and data lines 10. In FIG. 3, the gate lines 3 extend transversely, the data lines 10 extend longitudinally, and the data lines 10 and the gate lines 3 cross over and a pixel unit is defined by the lines; in the figure, gate lines 31 and 32 are gate lines adjacent to each other, and located on the upper and lower sides of one pixel unit, respectively. The common electrode 2, such as a plate-like electrode, is formed on a base substrate 1; the pixel electrode 9 is formed over the common electrode 2 and overlaps with it; the common electrode 2 is a slit electrode, namely, it includes a plurality of slits, and the strip-like portions of the pixel electrode are between the slits and outside the slits. The thin film transistor comprises source-and-drain electrodes 6, a part of a gate line 3 is used as a gate electrode, and an active layer is formed between the part of the gate line 3 as the gate electrode and the source-and-drain electrodes 6. The source electrode and the drain electrode out of the source-and-drain electrodes 6 are disposed opposite to each other, and a part of the active layer between them constitutes a channel. One of the source-and-drain electrodes 6 is electrically connected to the pixel electrode 9 through the via hole, and the other one is electrically connected to a data line 10. The base substrate 1 is such as a glass substrate or a plastic substrate.

The pixel electrode 9 comprises a plurality of strip-like portions, and in FIG. 3, in one pixel unit, the part of the pixel electrode 9 at the lower side is placed to overlap a part of the gate line 31, and a part of the pixel electrode 9 at the upper side is placed to overlap a part of the gate line 32. For example, at least one of the strip-like portions of the pixel electrode 9 at the upper and lower sides is placed to overlap a part of a corresponding gate line (31, 32) entirely or in part. If the width of each of the strip-like portions is relatively large, then the pixel electrode 9 may have one strip-like portion that overlaps the gate line 31 or 32; if the width of each of the strip-like portions is relatively small, then the pixel electrode 9 may have two or more strip-like portions that overlap the gate line 31 or 32.

In an embodiment of the present disclosure, at least one strip-like portion of a pixel electrode is placed to overlap a part of a corresponding gate line entirely or in part. When two or more strip-like portions of a pixel electrode are placed to overlap partial regions of corresponding gate lines entirely or in part, this includes the following case: a first strip-like portion of the pixel electrode is placed to overlap a first region of a corresponding gate line entirely or in part, and a second strip-like portion of the pixel electrode is placed to overlap a second region of a corresponding gate line entirely or in part.

For example, as shown in FIG. 3, a part of a first strip-like portion 91 of the pixel electrode 9 in the uppermost part is placed to overlap a first region 311 of the corresponding gate line 31 (a part close to the pixel electrode 9 at the lower side of the gate line), and a part of a second strip-like portion 92 of the pixel electrode 9 in the lowermost part is placed to overlap a second region 322 of the corresponding gate line 32 (a part close to the pixel electrode 9 at the upper side of the gate line). Or, a part of the first strip-like portion 91 of the pixel electrode 9 is placed to overlap the first region 311 of the corresponding gate line 31, and the entirety of the second strip-like portion 92 of the pixel electrode 9 is placed to overlap the second region 322 of the corresponding gate line 32. Alternatively, the entirety of the first strip-like portion 91 of the pixel electrode 9 is placed to overlap the first region 311 of the corresponding gate line 31, and a part of the second strip-like portion 92 of the pixel electrode 9 is placed to overlap the second region 322 of the corresponding gate line 32. Or, the entirety of the first strip-like portion 91 of the pixel electrode 9 is placed to overlap the first region 311 of the corresponding gate line 31, and the entirety of the second strip-like portion 92 of the pixel electrode 9 is placed to overlap the second region 322 of the corresponding gate line 32.

Here, as to a certain gate line 3, a first region and a second region, which correspond to the pixel electrodes of adjacent pixel units in the upper and lower direction, are adjacent to each other, and the sum of the areas of the two regions is less than the area of the part of the gate line that corresponds to these pixel units, namely, the first region and the second region are apart from each other and do not overlap with each other. For example, as to the part of the gate line 32 that corresponds to the pixel electrode 9 shown in FIG. 3, the second region 322 on the top side and the first region 321 on the bottom side are apart from each other.

Therefore, in the embodiment of the present disclosure, for a gate line, it is not fully covered by the pixel electrodes of the pixel units, which are separated from each other by the gate line and are adjacent to each other, at the place that corresponds to the pixel units; namely, there is at least a space “b” at the place that corresponds to the pixel units for the gate line.

In the pixel structure for the array substrate shown in FIG. 3, the respective strip-like portions of a pixel electrode are placed in parallel, and there is an interval (a slit) between adjacent strip-like portions of the pixel electrode. Furthermore, at one or two ends adjacent strip-like portions of the pixel electrode may be connected, respectively. The width of each of the strip-like portions of the pixel electrode is “a.”

Here, a part of at least one strip-like portion of a pixel electrode is placed to overlap a part of a corresponding gate line. The interval between the strip-like portions of the pixel electrodes of two pixel units, which are adjacent to each other in the extending direction of the data lines 10, is “b,” namely, the interval between these two pixel electrodes at the place that corresponds to the gate line is “b.”

The leaping voltage in this case is:

$$Δ {V}_{p} = \frac{( {V}_{gh} - {V}_{gl} ) \times ( {C}_{gs} + {C}_{gs 1} )}{( {C}_{st} + {C}_{lc} )} ( given {C}_{gs} << {C}_{st} + {C}_{lc} + {C}_{gs 1} ) \qquad ( 2 )$$

When the widths “a” of strip-like portions of a pixel electrode are increased, not only a storage capacitance Cₛₜ between the pixel electrode and a common electrode is increased, but also the interval between two adjacent pixel electrodes is decreased, namely, the interval “b” between the two adjacent pixel electrodes at the place that corresponds to a gate line is decreased as well. So, areas of the pixel electrodes covering the place that corresponds to the gate line are increased, and then storage capacitance C_{gsl} between a pixel electrode and a corresponding gate line is increased.

When the widths “a” of strip-like portions of a pixel electrode are decreased, not only storage capacitance Cₛₜ between the pixel electrode and a common electrode is decreased, but also the interval between two adjacent pixel electrodes is increased, namely, the interval “b” between the two adjacent pixel electrodes at the place that corresponds to a gate line is increased as well. So, areas of the pixel electrodes covering the place that corresponds to the gate line are decreased, and then storage capacitance C_{gsl} between a pixel electrode and a corresponding gate line is decreased as well.

As can be seen from the above, Cₛₜ and C_{gsl} are increased or decreased synchronously in accordance with variation in widths of strip-like portions of a pixel electrode. Thus, when widths of the strip-like portions of the pixel electrode are changed as a result of manufacturing processes, the difference between leaping voltages that are obtained in accordance with the formula (2) is smaller than the difference between leaping voltages that are obtained in accordance with the formula (1); thus, the sensitivity of a leaping voltage ΔVₚ to variation in widths of strip-like portions of a pixel electrode in the process is reduced.

Hereinafter, an embodiment of the present disclosure will be further described in detail in combination with drawings of the specification.

In the embodiment, a patterning process comprises: photoresist coating, exposing, developing, etching and other process. Each pixel structure in an array substrate is such as that shown in FIG. 3.

A manufacturing process of the array substrate may include the following steps.

Step 401: a gate electrode and a common electrode are formed on a substrate.

Firstly, a layer of metal thin film is deposited on the base substrate, and then with the use of a patterning process, the gate electrode and the common electrode are formed.

Here, the base substrate is usually a glass substrate. The metal thin film may be a single-layered film in which neodymium aluminum alloy (AlNd), aluminum (Al), molybdenum (Mo), copper (Cu), tungsten molybdenum alloy (MoW), chromium (Cr) or the like is used, or may be a composite film in which any combination of the above metal materials is used. That is, the material for the gate electrode and the common electrode may include one or more selected from the group consisting of Al, Mo, Cu, MoW and Cr.

Step 402: a gate insulating layer and an active layer are formed on the substrate with the gate electrode and the common electrode formed.

Firstly, the gate insulating layer is formed on the substrate with the gate electrode and the common electrode formed, so that the gate insulating layer covers the whole substrate, the gate electrode and the common electrode, and then the active layer is formed on the gate insulating layer; the area of the active layer is far smaller than that of the gate insulating layer. That is, on the gate insulating layer, the active layer is only formed in a place that corresponds to the gate electrode. For example, the active layer is formed of a semiconductor layer and a doped semiconductor layer that are formed in sequence, for example a silicon semiconductor material; and the active layer may also be of an oxide semiconductor material.

Here, the gate insulating layer and the active layer are each formed in such a manner that a thin film is deposited and then a patterning process is conducted.

For the gate insulating layer, a single-layered film of silicon nitride (SiNx), silicon-based oxide (SiOx), silicon oxynitride (SiOxNy) may be used, or a composite film of the above materials may also be used. A thin film of a-Si (amorphous silicon) is used for the semiconductor layer, and a thin film of N⁺ a-Si (amorphous silicon) is used for the doped semiconductor layer. Thus, the material for the gate insulating layer includes one or more selected from the group consisting of SiNx, SiOx, and SiOxNy. The material for the active layer includes: a-Si (amorphous silicon) for the semiconductor layer and N⁺ a-Si (amorphous silicon) for an ohmic contact layer.

Step 403: a data line, a source electrode and a drain electrode are formed on the gate insulating layer and the active layer.

A layer of source-and-drain metal thin film is deposited on the substrate with the active layer formed thereon. Then, the data line, the source electrode and the drain electrode are formed by using a patterning process for the data line, the source electrode and the drain electrode, and meanwhile, the doped semiconductor layer that is exposed is etched off by using an etching process, so as to form a TFT channel.

For the source-and-drain metal thin film, a single-layered film of Al, Mo, Cu, MoW, Cr or the like may be used, or a composite film of the above materials may be used. That is, the material for the data line, the source electrode and the drain electrode of a TFT include one or more selected from the group consisting of Al, Mo, Cu, MoW and Cr.

The gate insulating layer and the active layer are included between the gate electrode and the drain electrode, while only gate insulating layer is included between the common electrode and the drain electrode.

Step 404: a passivation layer is formed on the substrate on which the data line, the source electrode and the drain electrode have been finished.

A passivation-layer thin film is deposited on the substrate on which the data line, the source electrode and the drain electrode have been finished, and next, the passivation layer is formed through a patterning process. At a location over the drain electrode in the passivation layer, there is formed a via hole.

For the passivation-layer thin film, a single-layered film of SiNx, SiOx, SiOxNy may be used, or a composite film of the above materials may also be used. That is, the material for the passivation layer includes one or more selected from the group consisting of SiNx, SiOx, and SiOxNy.

Step 405, a pixel electrode is formed so as to finish the array substrate.

A layer of transparent conductive thin film is deposited on the substrate on which the passivation layer has been finished, and then, the pixel electrode that covers the via hole in the passivation layer is formed by using a patterning process for the pixel electrode. As such, the pixel electrode is connected to the drain electrode through the via hole on the passivation layer.

For the transparent conductive thin film, a single-layered film of indium tin oxide (ITO) and Indium zinc oxide (IZO) may be used, or a multilayered film of the above materials may be used. That is, the material for the conductive thin film includes one or two of indium tin oxide (ITO) and Indium zinc oxide (IZO).

In the embodiment of the present disclosure, a pixel electrode includes a plurality of strip-like portions. The strip-like portions of the pixel electrode are placed in parallel, there is an interval (a slit) between two adjacent strip-like portions of the pixel electrode, and the two adjacent strip-like portions of the pixel electrode are connected at two ends. Furthermore, at least one strip-like portion of the pixel electrode is placed to overlap a part of a corresponding gate line entirely or in part.

With the manufacturing process of the array substrate according to the above embodiment, in each pixel structure, a pixel electrode is extended to an overlapping location with a corresponding gate line, so that at least one strip-like portion of the pixel electrode is placed to overlap a part of the corresponding gate line entirely or in part. Thus, additional storage capacitance C_{gsl} is produced between the pixel electrode and the gate line, and the storage capacitance C_{gsl} between the pixel electrode and the gate line and the storage capacitance Cₛₜ between the pixel electrode and a common electrode can be increased or decreased synchronously in accordance with variation in widths of the strip-like portions of the pixel electrode. Thus, sensitivity of a leaping voltage ΔVₚ to variation in the widths “a” of the strip-like portions of the pixel electrode in the process can be reduced effectively, and further, the probability that uneven brightness of the panel of a TFT-LCD occurs due to the process is reduced. Furthermore, because stability of the leaping voltage ΔVₚ is enhanced, crosstalk between data lines can also be eliminated. Thereby, the occurrence rate of flicker and afterimage is decreased, and the picture quality is improved.

In the above embodiment, four patterning processes are used to form the array substrate, but the embodiments of the present disclosure are not limited thereto. Rather, five, six or more patterning processes may also be used to form an array substrate.

For example, the method by which a TFT-LCD array substrate is completed through five patterning processes includes: forming a transparent common electrode on a glass substrate through a first patterning process; forming gate lines and data lines that are even-numbered through a second patterning process; forming an active layer, source and drain metal electrodes of thin film transistors (TFTs), and data lines that are odd-numbered through a third patterning process; forming a passivation layer and via holes through a fourth patterning process; depositing a transparent conductive layer, and forming pixel electrodes through a fifth patterning process. A pixel electrode formed by the fifth patterning process includes a plurality of strip-like portions that are arranged in parallel, and there is an interval between two adjacent strip-like portions of the pixel electrode. Moreover, the two adjacent strip-like portions of the pixel electrode may be connected at one or two corresponding ends, and at least one strip-like portion of the pixel electrode is placed to overlap a part of a corresponding gate line entirely or in part. Other specific manufacturing procedures will not be described any more.

Certainly, in an embodiment of the present disclosure, it is possible that the array substrate of a liquid crystal display includes only one above-stated pixel structure, and other pixel structures that are constructed in an existing configuration; and it may also be possible that two, three or more above-stated pixel structures are included.

In the embodiments of the present disclosure, in a pixel structure of the array substrate of a liquid crystal display, a pixel electrode includes a plurality of strip-like portions, and at least one strip-like portion of the pixel electrode is placed to overlap a part of a corresponding gate line entirely or in part. Thus, the storage capacitance C_{gsl}, between the pixel electrode and the gate line and the storage capacitance Cₛₜ between the pixel electrode and a common electrode can be increased or decreased synchronously in accordance with variation in widths “a” of the strip-like portions of the pixel electrode. Thus, sensitivity of a leaping voltage ΔVₚ to variation in the widths “a” of the strip-like portions of the pixel electrode in the process is reduced, and further, the probability that uneven brightness of the panel of a TFT-LCD occurs due to the process is reduced. Thereby, stability of the picture quality is improved.

The descriptions made above are merely exemplary embodiments of the present disclosure, but are not used to limit the protection scope of the present disclosure. The protection scope of the present disclosure is determined by attached claims.

1. A pixel structure for a liquid crystal display, comprising: gate lines disposed on two opposite sides, data lines disposed on other two opposite sides, a common electrode, a thin film transistor and a pixel electrode,
wherein the pixel electrode includes a plurality of strip-like portions, and at least one of the strip-like portions of the pixel electrode is placed to overlap a part of a corresponding gate line entirely or in part.

2. The pixel structure claimed as claim 1, wherein the strip-like portions of the pixel electrode are arranged in parallel, and there is an interval between two of the strip-like portions of the pixel electrode that are adjacent.

3. The pixel structure claimed as claim 1, wherein a first strip-like portion of the pixel electrode is placed to overlap a first region of the gate line on one adjacent side, and a second strip-like portion of the pixel electrode is placed to overlap a second region of the gate line on the other adjacent side.

4. The pixel structure claimed as claim 3, wherein a sum of areas of the first region and the second region of a same gate line is smaller than the area of a part of the gate line that corresponds to the pixel electrode.

5. The pixel structure claimed as claim 1, wherein a gate insulating layer and a passivation layer are provided between the gate lines and the pixel electrode.

6. The pixel structure claimed as claim 1, wherein a gate insulating layer and a passivation layer are provided between the common electrode and the pixel electrode.

7. The pixel structure claimed as claim 5, wherein materials for the gate insulating layer and the passivation layer include one or more selected from the group of consisting of SiNx, SiOx and SiOxNy.

8. The pixel structure claimed as claim 1, wherein materials for the common electrode, the gate lines and the data lines include one or more selected from the group of consisting of Al, Mo, Cu, Mo, W and Cr.

9. The pixel structure claimed as claim 1, wherein a material for the pixel electrode includes one or two of indium tin oxide (ITO) and indium zinc oxide (IZO).

10. An array substrate of a liquid crystal display, comprising at least one pixel structure claimed as claim 1.

11. A liquid crystal display, comprising the array substrate claimed as claim 10.

12. The pixel structure claimed as claim 2, wherein a first strip-like portion of the pixel electrode is placed to overlap a first region of the gate line on one adjacent side, and a second strip-like portion of the pixel electrode is placed to overlap a second region of the gate line on the other adjacent side.

13. The pixel structure claimed as claim 12, wherein a sum of areas of the first region and the second region of a same gate line is smaller than the area of a part of the gate line that corresponds to the pixel electrode.

14. The pixel structure claimed as claim 2, wherein materials for the gate insulating layer and the passivation layer include one or more selected from the group consisting of SiNx, SiOx and SiOxNy.
